(19) United States
(12) Patent Application Publication
(10) Pub. No.: US 2025/0140662 A1
(43) Pub. Date: May 1, 2025

(54) POWER MODULE HAVING A CIRCUIT CARRIER AND POWER MODULE BRIDGE HAVING A NUMBER OF POWER MODULES

(71) Applicant: Robert Bosch GmbH, Stuttgart (DE)

(72) Inventor: Irfan Aydogmus, Nuertingen (DE)

(21) Appl. No.: 18/915,642

(22) Filed: Oct. 15, 2024

(30) Foreign Application Priority Data
Oct. 26, 2023 (DE) 10 2023 210 593.4

(51) Int. Cl. H01L 23/498; H01L 23/367; H01L 23/538; H05K 1/18

(52) U.S. Cl. CPC H01L 23/49811; H01L 23/367; H01L 23/5386; H01L 23/5387; H05K 1/182; H05K 2201/1059

(57) ABSTRACT

A power module. The power module has a first circuit carrier, containing a carrier substrate, a first conductor structure with an external contact region, at least one second conductor structure with at least one external contact region, and a further, third conductor structure with an external contact region, with a number of semiconductor components arranged individually or in groups. The power module is assigned a multifunction frame in which a T+ bridge, a T− bridge, and a phase bridge are accommodated so as to be spatially decoupled from the power module. A power module bridge having a number of power modules which are accommodated on a cooling surface, is also described.

### FIELD

The present invention relates to a power module having a circuit carrier, containing a carrier substrate, having a first conductor structure with an external contact region, at least one second conductor structure with at least one external contact region and a further, third conductor structure with an external contact region, with a number of semiconductor components arranged individually or in groups. Furthermore, the present invention relates to a power module bridge having a number of power modules which are accommodated on a common cooling surface.

### BACKGROUND INFORMATION

In the related art, power modules, which are installed for example in a power module bridge, are additionally molded. During molding, the power module is embedded in a solid protective housing, for example made of plastic (molding compound). The molding compound is used to enclose and protect the interior of the power module. However, these enclosures of the power module by means of molding compound are not particularly resistant to cracks.

German Patent Application No. DE 11 2017 004 390 T5 describes a power module which has the following features: an insulating substrate with a front side to which a power semiconductor element is fastened; a base plate connected to a rear side of the insulating substrate; a housing fastened to the base plate and surrounding the insulating substrate; a cover fastened to the housing and forming a sealed region, and a silicone gel serving as a filling element which fills the entire sealed region and has an internal stress which acts as a compressive stress.

German Patent Application No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the corresponding first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case one second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case one first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes electrical contacting between a flexible film, which has at least one conductor track, and at least one electrical contact of a sensor device or control device. In this case, an end portion of the flexible film is electrically contacted at a contact point by heat input, wherein the end portion of the flexible film is placed against protruding electrical contacts at the contact point. The end portion of the flexible film is designed with a breaking wave shape, in particular as a deflection.

### SUMMARY

According to the present invention, a power module is provided, having a first circuit carrier, containing a carrier substrate, having a first conductor structure with an external contact region, at least one second conductor structure with at least one external contact region and a further, third conductor structure with an external contact region, wherein a number of semiconductor components arranged individually or in groups are provided. The power module is assigned a multifunction frame in which a T+ bridge, a T− bridge and a phase bridge are accommodated so as to be spatially decoupled from the power module.

Due to the assignment of the multifunction frame to the power module proposed according to the present invention, current-conducting components can be arranged spatially and in a decoupled manner outside the expensive and limited area of the power module and, in particular, in a thermally decoupled manner.

In an advantageous embodiment of the power module provided according to the present invention, it is provided that the multifunction frame can be arranged above, below or to the side of the power module, as viewed in the Z direction. The design variants mentioned make it possible to take into account customer requirements with regard to the available installation space.

In an advantageous development of the power module provided according to the present invention, the T+ bridge and the T− bridge are accommodated in the multifunction frame in a horizontal arrangement, wherein a distance therebetween is minimized.

Alternatively, according to an example embodiment of the present invention, it is possible to design the power module in such a way that the T+ bridge and the T− bridge are accommodated in the multifunction frame in a vertical arrangement and a distance therebetween is minimized. Finally, in a further design variant, there is the option of designing the power module proposed according to the present invention in such a way that the T+ bridge and the T− bridge are accommodated next to one another in the multifunction frame and a distance therebetween is minimized.

The design variants described above advantageously make it possible to ensure that the minimized distance between the T+ bridge and the T− bridge means that magnetic fields occurring in the current-conducting T+ or T− bridges cancel each other out, so that a low-inductance design is possible. A low-inductance design, in turn, allows for short switching times, which is extremely beneficial to the switching behavior of the power module proposed according to the present invention.

In an advantageous development of the power module provided according to the present invention, an insulation layer, in particular designed as insulation paper or cardboard, is arranged in the multifunction frame between the T+ bridge and the T− bridge. This allows the distances between the T+ bridge and the T− bridge to be significantly minimized.

Advantageously, the power module provided according to the present invention provides that the T+ bridge and the T− bridge can be contacted via press-in pins. Press-in pins are a proven technology for ensuring robust electrical contacting over the service life.

In an advantageous development of the power module provided according to the present invention, it is provided that, in the joined state of the power module with the multifunction frame, the T+ bridge, the T− bridge and the phase bridge are arranged in a first level which runs above or below a second level in which the power module is arranged with semiconductor components arranged individually or in groups on its base surface. The arrangement of the above-mentioned levels allows in particular thermal decoupling and the displacement of the current-conducting components into the multifunction frame in which said T+ bridge, T− bridge and phase bridge are arranged.

The power module provided according to an example embodiment of the present invention is further characterized in that the multifunction frame assigned to the power module in the Z direction is surrounded by a cover made of a plastics material or by a molding compound. The cover made of a plastics material or the molding compound provides effective protection against the effects of environmental influences. In the power module proposed according to the present invention, it is further provided that the T+ bridge and/or the T− bridge is provided with integrated contact surfaces.

In the power module provided according to the present invention, it is provided that the external contact regions are displaced in the Z direction with respect to the power module into the multifunction frame assigned thereto. The displacement of the external contact regions from the power module into the multifunction frame also contributes to improved utilization of the surface of the circuit carrier or the chip surface.

In the power module provided according to the present invention, the multifunction frame assigned to the power module is provided with a number of press-in pins, of which a selected number are accessible for signal tapping.

Furthermore, the present invention relates to a power module bridge having a number of power modules, wherein the power modules are accommodated on a cooling surface and the power module bridge is placed in a lateral arrangement next to a battery system and is electrically connected thereto via a connecting device. Alternatively, it is possible to place a number of power modules accommodated on a cooling surface, and the power module bridge comprising a number of power modules, above or below a battery system and to electrically connect the power module bridge to the battery system via a corresponding connecting device.

The solution provided according to the present invention is characterized in that a surface, in particular a base surface of the power module, which is equipped with semiconductor elements, whether individually or in groups, can be better utilized because the surface which is otherwise used for current-conducting paths is relocated into another level of a multifunction frame. The multifunction frame assigned to the power module can be arranged both above and below the power module as viewed in the Z direction. Furthermore, it is also possible to arrange the multifunction frame next to the power module, as well as spatially and thermally decoupled therefrom. A further advantage of the solution proposed according to the present invention is that the current-conducting paths in the form of the T+ bridge and the T− bridge are accommodated in a horizontal arrangement, in a vertical arrangement or in a side-by-side arrangement in the multifunction frame. If the distance between the T+ bridge and the T− bridge is minimized, the magnetic fields which arise in the T+ bridges or T− bridges due to the current flow cancel each other out. This in turn results in a low-inductance connection being achieved. A low-inductance connection is extremely advantageous with regard to short switching times and significantly increases the performance of the power module proposed according to the present invention with the multifunction frame assigned thereto. The solution provided according to the present invention can further reduce the degree of complexity of the power module. If the semiconductor components accommodated individually or in groups in the power module are arranged on its base surface, extremely advantageous cooling and thus heat dissipation of the semiconductor components can be achieved via a cooling surface. The cooling surface can be connected to the underside of the power module by means of a flat sintered connection or by means of a solder/adhesive connection. This results in short paths via which the waste heat generated during operation of the semiconductor components can be dissipated and transported away by a cooling medium. Standardized interfaces for signal transmission can be realized in the form of press-in studs. The use of press-in studs or press-in pins is a common and robust way to achieve electrical connections with overmolded components. If the equipped and electrically contacted power module or the multifunction frame assigned thereto is provided with a cover made of plastics material or a molding compound, it can be advantageously protected against environmental and temperature influences as well as pollutants. The press-in pins protruding beyond the cover still allow electrical contact to be made between the arrangement of the power module and the multifunction frame assigned thereto, whether arranged above, below or to the side of the power module. Depending on the requirement or the electrical loads to be controlled, the power module proposed according to the present invention can comprise 12, 8 or 4 semiconductor components, wherein the semiconductor components can be MOSFETs, transistors, IGBTs, diodes and the like. The use of press-in pins also allows standard electrical contacting for the power contacts. With regard to the contacting of the power module proposed according to the present invention with the press-in pins assigned thereto, the implementation of integrally bonded connections, for example by means of welding, is superfluous. The press-in pins allow for effective and robust electrical contacting.

### BRIEF DESCRIPTION OF THE DRAWINGS

Example embodiments of the present invention are explained in greater detail with reference to the figures and the following description.

FIG. 1 is a plan view of a first circuit carrier of a power module, containing a carrier substrate, and a possible arrangement of semiconductor components, according to an example embodiment of the present invention.

FIG. 2 is a plan view of a power module with separate cooling and layout surfaces with laterally arranged regions for press-in pins, according to an example embodiment of the present invention.

FIG. 3 shows an arrangement of a power module accommodated on a cooling surface and a multifunction frame arranged thereabove in the Z direction, according to an example embodiment of the present invention.

FIG. 4 shows a multifunction frame which is joined to a power module in the assembly direction, according to an example embodiment of the present invention.

FIG. 5 is a perspective view of a plastics-coated arrangement of a multifunction frame and power module, according to an example embodiment of the present invention.

FIG. 6 is an exploded view of the components of the multifunction frame, according to an example embodiment of the present invention.

FIG. 7 is a perspective view of the multifunction frame with T+ bridges and T− bridges arranged therein, according to an example embodiment of the present invention.

FIG. 8A shows a horizontal arrangement of a T+ bridge and a T− bridge, according to an example embodiment of the present invention.

FIG. 8B, 8C are schematic representations of possible arrangements of the T+ bridge and the T− bridge in vertical arrangement, according to an example embodiment of the present invention.

FIG. 9 is a plan view of a power module bridge with power modules arranged next to one another on a cooling surface, according to an example embodiment of the present invention.

FIG. 10 shows a possible arrangement of a power module bridge shown in FIG. 9 next to a battery system, according to an example embodiment of the present invention.

### DETAILED DESCRIPTION OF EXAMPLE EMBODIMENTS

In the following description of the embodiments of the present invention, identical or similar elements are denoted by the same reference signs, and a repeated description of these elements in individual cases is dispensed with. The figures show the subject matter of the present invention only schematically.

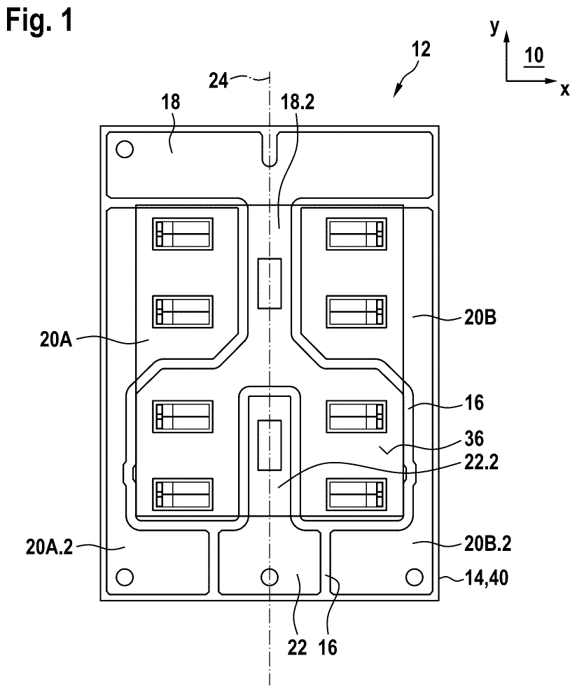

FIG. 1 is a plan view of a power module 12, in particular of its first circuit carrier 14.

From the plan view according to FIG. 1 it can be seen that a carrier substrate 40 of the first circuit carrier 14 is provided with a number of conductor structures 18, 20A, 20B, 22. The first circuit carrier 14 extends in an X, Y plane 10, wherein the first circuit carrier 14 is provided with an electrical insulation layer 16. On said insulation layer—separated by channel-shaped interruptions—there is a first conductor structure 18 which has an external contact region 18.2. Furthermore, second conductor structures 20A, 20B are located opposite one another on the first circuit carrier 14, symmetrically to a central longitudinal axis 24 of the power module 12. Each of the two second conductor structures 20A, 20B comprises an external contact region 20A.2, 20B.2. Finally, a third conductor structure 22 that has at least one external contact region 22.2 is applied to the first circuit carrier 14 or to its electrical insulation layer 16.

The aforementioned conductor structures 18, 20A, 20B, 22 are electrically separated from one another and applied substantially symmetrically to the central longitudinal axis 24 on the first circuit carrier 14. Position 36 designates an active surface; a layout surface around this for the current conduction is designated by reference sign 38. For example, AMB (active metal brazing), which contains OFC (oxygen-free copper)/Si₃N₄/OFC, can be selected as the carrier substrate 40 of the first circuit carrier 14.

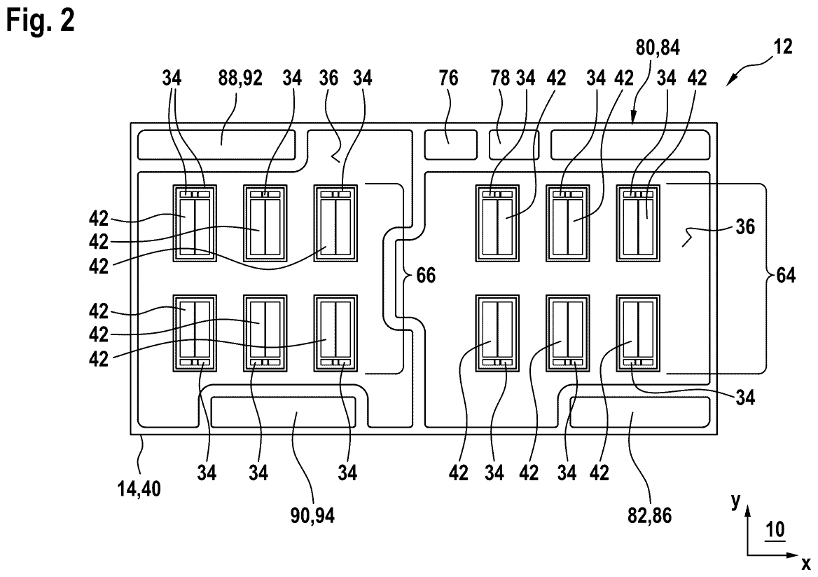

The representation according to FIG. 2 shows a plan view of the power module 12, wherein in this schematic representation semiconductor components 42 are arranged on active surfaces 36, which can be, for example, transistors, MOSFETs or other semiconductor components which can be used as semiconductor switches. FIG. 2 shows that a first group 64 of semiconductor components 42 is accommodated on the active surfaces 36. The individual semiconductor components 42 can be designed, for example, as MOSFETs and have control terminals 34 on their outer sides, via which the individual semiconductor components 42 of the first group 64 of semiconductor components 42 can be controlled (not shown in more detail). A second group 66 of semiconductor components 42 is arranged analogously to the first group 64, and this second group can also be MOSFETs, on the outer region of which control terminals 34 are formed. The semiconductor components 42 of the second group 66 of semiconductor components 42 can be controlled from the outside via the control terminals 34, although this is not shown in more detail in the representation according to FIG. 2.

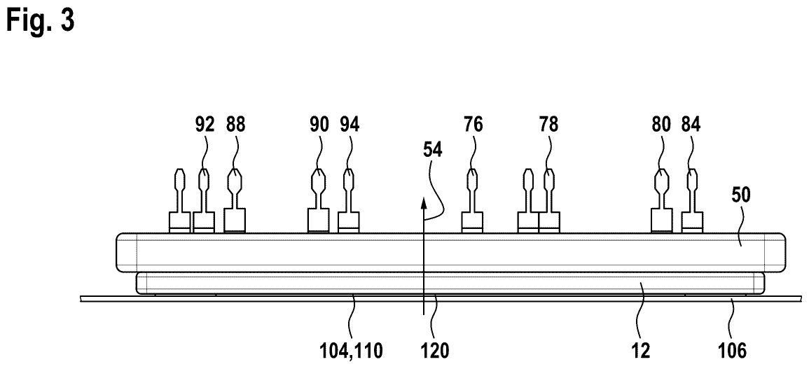

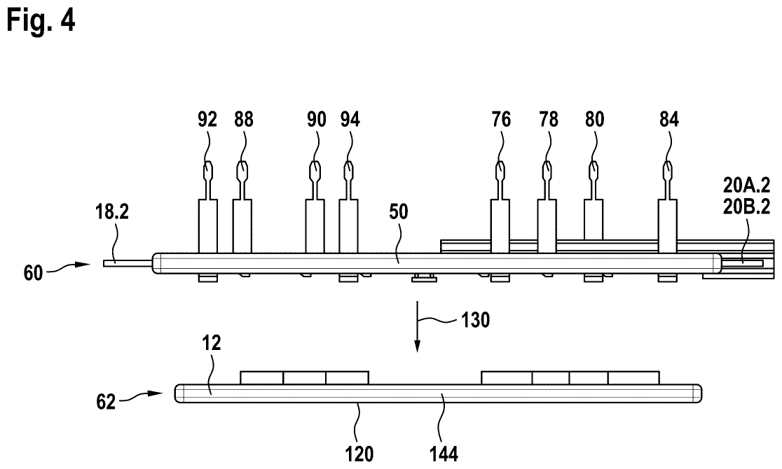

Furthermore, it can be seen from the plan view according to FIG. 2 that in the X, Y plane 10 shown in FIG. 2, regions are provided on the longitudinal sides of the first circuit carrier 14 in the form of a carrier substrate 40, in which regions press-in pins 76-94 protrude into the plane of the drawing according to FIG. 2. Specifically, these are first and second press-in pins 76, 78, third and fourth press-in pins 80, 82 and, arranged opposite one another, fifth and sixth press-in pins 84, 86. Seventh and eighth press-in pins 88, 90 and ninth and tenth press-in pins 92, 94 are provided in the region of the opposite end face of the first circuit carrier 14. The spatial arrangement of the press-in pins 76, 78, 80, 82, 84, 86, 88, 90, 92, 94 can be seen in more detail in the representations in FIGS. 3 and 4.

From the side view according to FIG. 3 it can be seen that a power module 12, shown here from the outside, is supported with its underside 120 on a cooling surface 106. As viewed in the Z direction 54, a multifunction frame 50 is located above the power module 12. On the upper side of the multifunction frame 50 shown from the side in FIG. 3, the individual press-in pins 76, 78, 80, 82, 84, 86, 88, 90, 92, 94, which in this case lie in a drawing plane, protrude vertically upward. The press-in pins allow electrical contact to be made in a robust and simple manner within the multifunction frame 50 or the power module 12 arranged underneath.

FIG. 4 shows that the multifunction frame 50, which is constructed similarly to FIG. 3, is placed on the power module 12 in the assembly direction 130. The multifunction frame 50 represents a first level 60, whereas the power module 12, in particular its base 144, represents a second level 62. In the representation according to FIG. 4, it can be seen that the external contact regions 18.2, 20A.2, 20B.2 shown in FIG. 1 and the external contact region 22.2 not shown in FIG. 4 can be displaced from the power module 12, i.e. from the second level 62 into the first level 60. The multifunction frame 50 as shown in FIG. 4 has a number of press-in pins 76-94 which differs from the representation in FIG. 3.

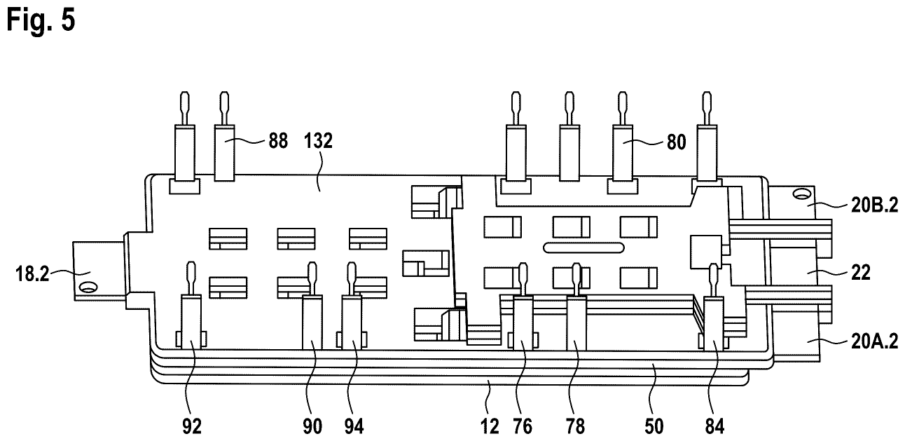

From the perspective plan view according to FIG. 5, it can be seen that the external contact regions 18.2 protrude laterally on the short end faces of the multifunction frame 50 or from its cover and the external contact regions 20A.2, 20B.2 protrude opposite these, so that they can be electrically contacted with other electrical components, for example by means of integrally bonded connections. The perspective plan view according to FIG. 5 further shows that the multifunction frame 50 comprises a cover made of plastics material 132, by means of which the components arranged in the multifunction frame 50, in particular the current-conducting components arranged there, are protected from the outside. In order to allow contacting of the components arranged in the multifunction frame 50 or in the underlying power module 12, in particular the semiconductor components 42, as well as the components arranged in the multifunction frame, the press-in pins, only a few of which are shown in FIG. 5, protrude beyond the upper side of the cover of the multifunction frame 50 made of plastics material 132.

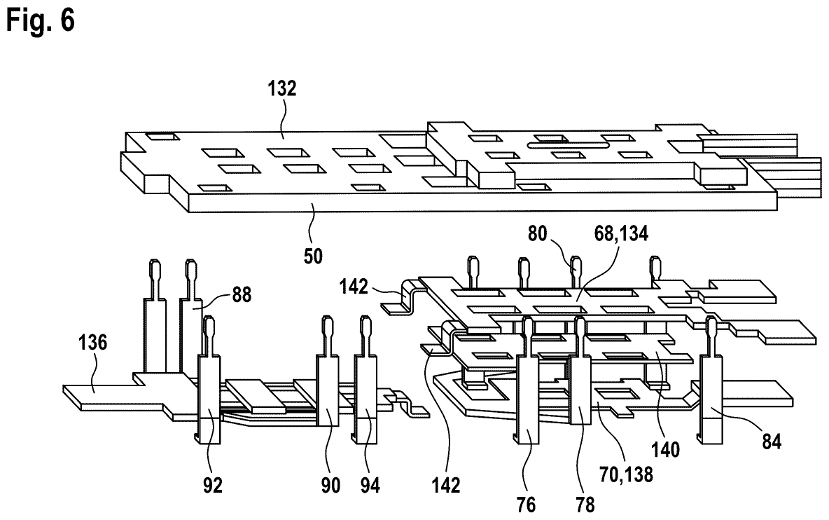

The representation in FIG. 6 shows an exploded view of the multifunction frame 50 and the components enclosed thereby. These are a T+ bridge 134, a phase bridge 136 and a T− bridge 138. These can also be referred to as the first current-conducting contact surface 68 or the second current-conducting contact surface 70.

The exploded view according to FIG. 6 also shows that the phase bridge 136 can be electrically contacted laterally via the seventh press-in pin 88 and the tenth press-in pin 94, shown here by way of example. The additional press-in pins assigned to the phase bridge 136, namely the ninth and tenth press-in pins 92 and 94, can be used to contact semiconductor components 42 which are not shown in the exploded view according to FIG. 6 but are arranged on the base 144 of the power module 12.

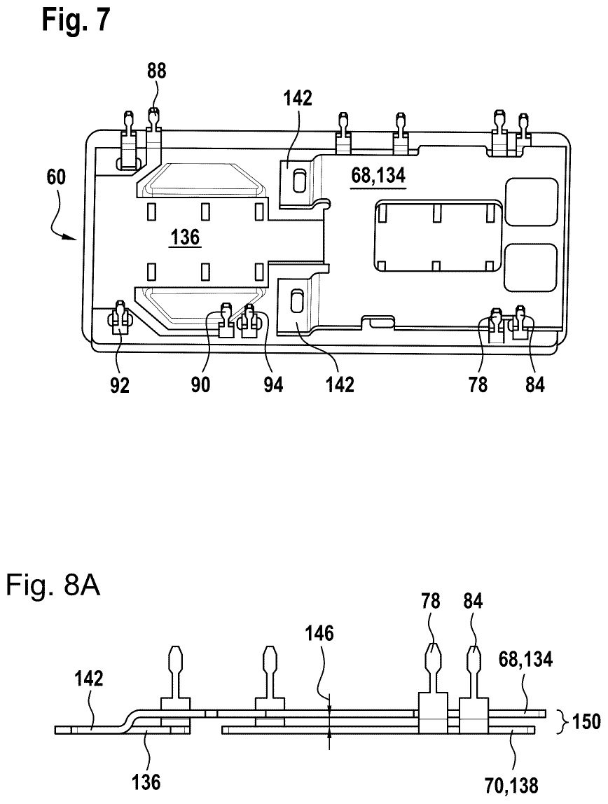

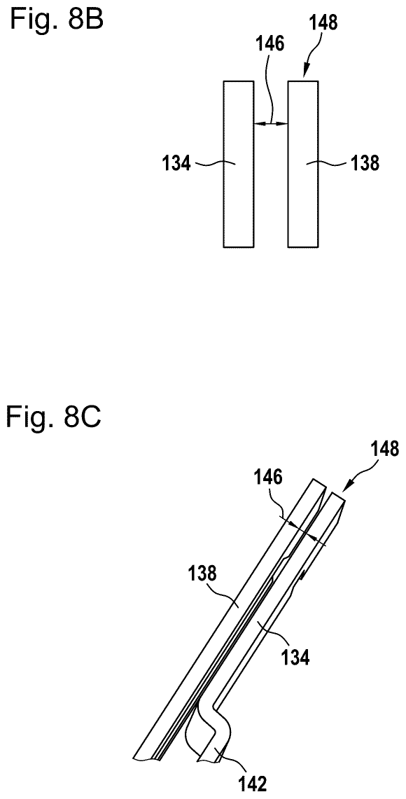

Furthermore, the representation according to FIG. 6 shows that the T+ bridge 134 and the T− bridge 138 are arranged one above the other. Between these, an insulation layer 140 made of paper or cardboard is arranged. The T+ bridge 134 can be electrically contacted via contact strips 142 (see also perspective view according to FIG. 7). The insulation layer 140, which is located between the T+ bridge 134 and the T− bridge 138, separates the bridges from each other in the vertical direction. The insulation layer 140 can also define a distance 146 as indicated in FIG. 8A. The smaller the distance 146 between the T+ bridge 134 and the T− bridge 138 can be set, the greater the degree of mutual cancellation of the magnetic fields running in the T+ bridge 134 or the T− bridge 138 that can be achieved.

The perspective view according to FIG. 7 shows the first level 60, which is defined by the built-in components in the multifunction frame 50. Analogously to the representation in FIG. 6, the phase bridge 136 can be contacted via the seventh press-in pin 88 and the eighth press-in pin 90. The semiconductor components 42 arranged in the power module 12 can be electrically contacted or controlled via the additional press-in pins 92, 94 shown here, which protrude through the multifunction frame 50 in the vertical direction. In the right part of the perspective plan view according to FIG. 7, the T+ bridge 134 (first current-conducting contact surface 68) is shown, under which the T− bridge 138 is located in the exploded view according to FIG. 6.

From the side view according to FIG. 8A it can be seen that in the multifunction frame 50, which is not shown in FIG. 8A, the T+ bridge 134 and the T− bridge 138 run in a horizontal arrangement 150, forming a small distance 146 in the vertical direction. The smaller the distance 146 between the T+ bridge 134 and the T− bridge 138 can be selected, the more favorable the low-inductance connection. The small distance 146 between the components T+ bridge 134 and T− bridge 138 arranged in a horizontal arrangement 150 advantageously allows the magnetic fields which form in the T+ bridge 134 and the T− bridge 138 to cancel each other out during operation. This ensures a low-inductance connection, which allows very short switching times of the electronic components in the form of MOSFETS, IGBTS, diodes, etc. The side view according to FIG. 8A also shows the contact strips 142, which extend partly parallel to the phase bridge 136.

FIG. 8B and 8C show that, as an alternative to the representation according to FIG. 8A with the horizontal arrangement 150 shown there, the T+ bridge 134 and the T− bridge 138 can also be designed in a vertical arrangement 148. In the vertical arrangement 148, too, the distance 146 between the T+ bridge 134 and the T− bridge 138 can advantageously be minimized in the installed state. In the vertical arrangement 148, too, the smaller the distance 146 between the T+ bridge 134 and the T− bridge 138 can be kept, the greater the mutual cancellation of the magnetic fields running in the current-conducting components T+ bridge 134 and T− bridge 138 can be achieved. Analogously to the horizontal arrangement 150 according to FIG. 8A, this also allows for a low-inductance connection, which allows for short switching times of the semiconductor components 42. The same applies analogously to the representation according to FIG. 8C.

From FIG. 8A, 8B, and 8C it follows that the arrangement of the T+ bridge 134 and the T− bridge 138 within the function frame 50 allows for a low-inductance connection, which allows for short switching times for the electronic semiconductor components 42 in the form of MOSFETS, IGBTs, diodes or the like arranged in the second level 62, preferably on the base 144 of the power module 12.

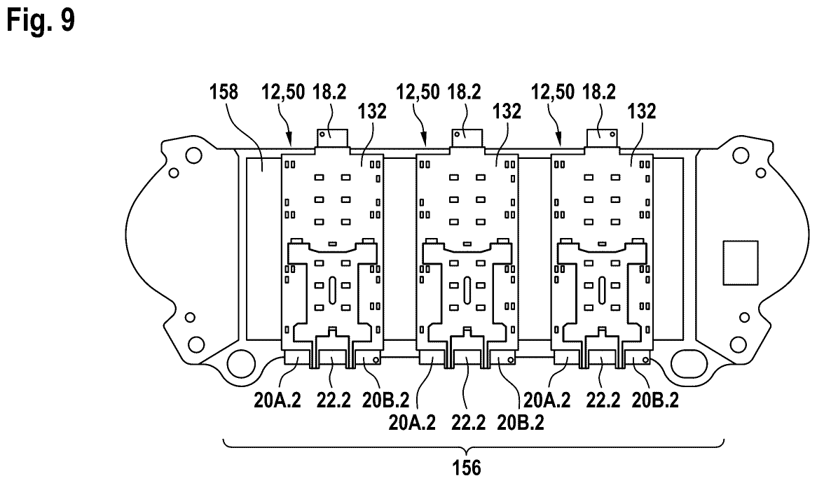

The plan view according to FIG. 9 shows a power module bridge 156. This has a number of power modules 12 with a multifunction frame 50 arranged thereabove. FIG. 9 shows that, in this design variant of the power module bridge 156, three power modules 12 are arranged next to one another on a cooling surface 158. The external contact regions 18.2, 20A.2, 20B.2 and 22.2 protruding from the short end faces of the multifunction frame 50 are used to contact the power modules 12 which are covered by the multifunction frame. The cooling surface 158, on which the power modules 12 are accommodated for the heat dissipation thereof, has a cooling medium flowing therethrough which dissipates the heat generated there during operation of the power modules 12.

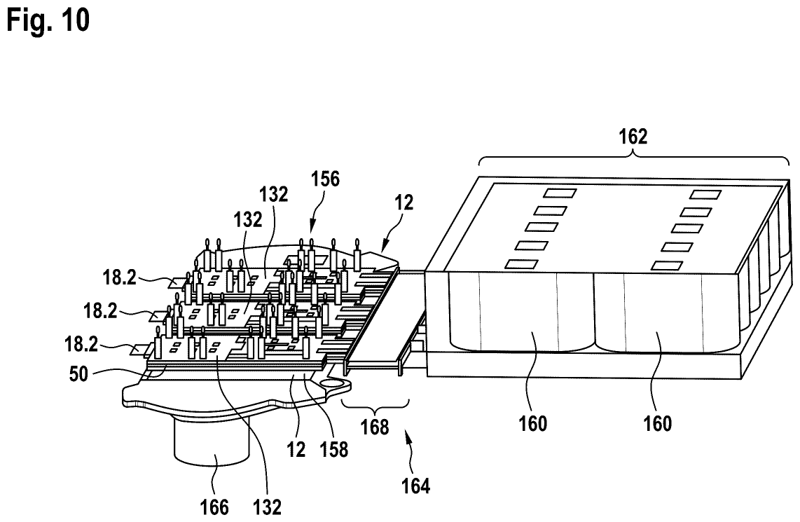

FIG. 10 shows a possible arrangement of the power module bridge 156 shown in FIG. 9 in relation to a battery system 162.

FIG. 10 shows that the power module bridge 156 in the representation according to FIG. 10 is arranged in a lateral arrangement 164 with respect to the battery system 162. The battery system 162 comprises a number of battery cells 160, which are only partially shown in the representation according to FIG. 10. The lateral arrangement 164 is characterized in that, in this design variant of the connection of the power module bridge 156, the latter is placed to the side of the power module bridge 156 via a connecting device 168. As can be further seen from the representation in FIG. 10, the function frame 50 and the press-in pins protrude vertically upward beyond the upper side of the cover made of plastics material 132. The press-in pins, which are not described in more detail here, are used to electrically contact the power modules 12 or to tap signals. From the representation according to FIG. 10 it is further apparent that the cooling surface 158 of the power module bridge 156 comprises at least one line connection 166 for the supply with a cooling medium. By integrating the cooling surface 158 into a continuous cooling circuit, continuous dissipation of the heat generated during operation of the semiconductor components 42 of the power modules 12 can be ensured. It can also be seen from the representation according to FIG. 10 that the external contact regions 18.2, which are displaced from the level of the power module 12 (cf. second level 62) into the first level 60, i.e. into the multifunction frame 50, can be electrically contacted from the side. In contrast, the press-in pins protruding beyond the upper side of the multifunction frame 50 can be electrically contacted from the upper side of the power module bridge 156. Instead of the lateral arrangement 164 of the power module bridge 156 in relation to the battery system 162 shown in FIG. 10, the power module bridge 156 can also be electrically contacted on the upper side of the battery system 162 or on its underside. In this case, the design of the connecting device 168 would be different and, depending on the connection plane, would be formed accordingly in the Z direction 54.

The present invention is not limited to the embodiments described here and the aspects emphasized therein. Rather, a large number of modifications are possible within the range indicated by the claims, which are within the scope of the activities of a person skilled in the art.

1-15. (canceled)

16. A power module, comprising:
a first circuit carrier containing a carrier substrate;
a first conductor structure with an external contact region;
at least one second conductor structure with at least one external contact region;
a further third conductor structure with an external contact region; and
a number of semiconductor components arranged individually or in groups;
wherein the power module is assigned a multifunction frame in which a T+ bridge, a T− bridge, and a phase bridge are accommodated so as to be spatially decoupled from the power module.

17. The power module according to claim 16, wherein the multifunction frame is arranged above or below the power module as viewed in a Z direction.

18. The power module according to claim 17. wherein the T+ bridge and the T− bridge are accommodated in the multifunction frame in a horizontal arrangement and a distance therebetween is minimized.

19. The power module according to claim 16, wherein the T+ bridge and the T− bridge are accommodated in the multifunction frame in a vertical arrangement and a distance therebetween is minimized.

20. The power module according to claim 16. wherein the T+ bridge and the T− bridge are accommodated next to one another in the multifunction frame and a distance therebetween is minimized.

21. The power module according to claim 16, wherein an insulation layer including an insulation paper or an insulation cardboard is arranged in the multifunction frame between the T+ bridge and the T− bridge.

22. The power module according to claim 16, wherein the T+ bridge can be contacted via press-in pins.

23. The power module according to claim 16, wherein the T-bridge can be contacted via press-in pins.

24. The power module according to claim 16, wherein, in a joined state of the power module with the multifunction frame, the T+ bridge, the T− bridge, and the phase bridge are arranged in a first level which lies above or below a second level in which the power module is accommodated with the semiconductor components arranged individually or in groups on a base surface.

25. The power module according to claim 16, wherein the multifunction frame assigned to the power module, in a Z direction, is surrounded by a cover made of a plastics material or by a molding compound.

26. The power module according to claim 16, wherein the T+ bridge and/or the T− bridge is provided with integrated contact surfaces.

27. The power module according to claim 16, wherein the external contact regions of the first, second, and third conductor structures are displaced in a Z direction with respect to the power module into the multifunction frame assigned thereto.

28. The power module according to claim 16, wherein the multifunction frame assigned to the power module is provided with a number of press-in pins, of which selected press-in pins are used for signal tapping.

29. A power module bridge, comprising:
a number of power modules, each including:
a first circuit carrier containing a carrier substrate,
a first conductor structure with an external contact region,
at least one second conductor structure with at least one external contact region,
a further third conductor structure with an external contact region; and
a number of semiconductor components arranged individually or in groups,
wherein the power module is assigned a multifunction frame in which a T+ bridge, a T− bridge, and a phase bridge are accommodated so as to be spatially decoupled from the power module,
wherein the power modules are accommodated on a cooling surface and the power module bridge is placed in a lateral arrangement next to a battery system and is connected thereto via a connecting device.

30. A power module bridge, comprising:
a number of power modules, each including:
a first circuit carrier containing a carrier substrate,
a first conductor structure with an external contact region,
at least one second conductor structure with at least one external contact region,
a further third conductor structure with an external contact region; and
a number of semiconductor components arranged individually or in groups,
wherein the power module is assigned a multifunction frame in which a T+ bridge, a T− bridge, and a phase bridge are accommodated so as to be spatially decoupled from the power module;
wherein the power modules are accommodated on a cooling surface and the power module bridge is placed above or below a battery system and is connected thereto via a connecting device.
